(19) United States
(12) Patent Application Publication
(10) Pub. No.: US 2011/0104896 A1
(43) Pub. Date: May 5, 2011

(54) METHOD OF MANUFACTURING SEMICONDUCTOR DEVICE AND SUBSTRATE PROCESSING APPARATUS

(75) Inventors: Kazuhiro HARADA, Toyama-shi (JP); Hideharu ITATANI, Nanto-shi (JP); Sadayoshi HORII, Toyama-shi (JP)

(73) Assignee: HITACHI KOKUSAI ELECTRIC, INC., Tokyo (JP)

(21) Appl. No.: 12/903,522

(22) Filed: Oct. 13, 2010

(30) Foreign Application Priority Data
Oct. 30, 2009 (JP) 2009-249627
Dec. 7, 2009 (JP) 2009-277711
Jun. 29, 2010 (JP) 2010-148047

(51) Int. Cl. H01L 21/443

(52) U.S. Cl. 438/680; 118/725; 257/E21.478

(57) ABSTRACT

There are provided a method of manufacturing a semiconductor device and a substrate processing apparatus, which are designed to prevent deterioration of the surface morphology of a Ni-containing film caused by dependence on an under layer, and to form a continuous film in a thin-film region. The method includes: loading a substrate into a process vessel; heating the substrate in the process vessel; pretreating the heated substrate by supplying a reducing gas into the process vessel and exhausting the reducing gas; removing the reducing gas remaining in the process vessel by supplying an inert gas into the process vessel and exhausting the inert gas; forming a nickel-containing film on the heated and pretreated substrate to a predetermined thickness by supplying a nickel-containing source into the process vessel and exhausting the nickel-containing source; and unloading the substrate from the process vessel.

### CROSS-REFERENCE TO RELATED PATENT APPLICATION

This U.S. non-provisional patent application claims priority under 35 U.S.C. §119 of Japanese Patent Application Nos. 2009-249627, filed on Oct. 30, 2009, 2009-277711, filed on Dec. 7, 2009, and 2010-148047, filed on Jun. 29, 2010, in the Japanese Patent Office, the entire contents of which are hereby incorporated by reference.

### BACKGROUND OF THE INVENTION

1. Field of the Invention

The present invention relates to a method of manufacturing a semiconductor device, the method including a process of treating a substrate in a process vessel, and a substrate processing apparatus suitable for the process.

2. Description of the Related Art

In a conventional NiSi process, Ni films are usually formed by a physical vapor deposition (PVD) method. However, since recent devices have three dimensional (3D) shapes and small sizes, it is necessary to form Ni films having good step coverage. The PVD method generally results in unsatisfactory step coverage, and thus the PVD method is not suitable for forming a film uniformly in the depth direction of a 3D shape. Thus, by using a chemical vapor deposition (CVD) method having good step coverage, it is possible to provide a NiSi process applicable to the next-generation devices (for example, refer to Patent Document 1).
[Patent Document 1] Japanese Unexamined Patent Application Publication No. 2008-231473

However, in a NiSi process, it is necessary to form a about 10-nm Ni film as a film containing low-resistance nickel (Ni). When a Ni film is formed by a CVD method, it is important that the Ni film is kept continuous in a thin-film region. For this, initial nucleation density is quite important, and the initial nucleation density is largely affected by the states of an under layer. According to the states of the under layer, the initial nucleation density may be decreased. In this case, a Ni film may not be continuously formed in a thin-film region (that is, the Ni film may become discontinuous), and the final surface morphology of the Ni film may be deteriorated.

In addition, the impurity concentration of a film is one of important factors to a CVD film forming process for the next-generation devices. Since the characteristics of a device are largely deteriorated if the impurity concentration of a film is high, it is preferable to reduce impurity concentration. However, in the case of some CVD sources, impurities included in the sources are easily transferred into a film during a film forming process. Thus, if a film forming process is performed by using such sources, the impurity concentration of a film may be high.

### SUMMARY OF THE INVENTION

An object of the present invention is to provide a method of manufacturing a semiconductor device and a substrate processing apparatus, which are designed to prevent deterioration of the surface morphology of a Ni-containing film caused by dependence on an under layer, and to form a continuous film in a thin-film region. Another object of the present invention is to provide a method of manufacturing a semiconductor device and a substrate processing apparatus, which are designed to prevent deterioration of device characteristics caused by impurities included in a film, and to form a high-quality film having a low impurity concentration.

According to an aspect of the present invention, there is provided a method of manufacturing a semiconductor device, the method including:

loading a substrate into a process vessel;

heating the substrate in the process vessel;

pretreating the heated substrate by supplying a reducing gas into the process vessel and exhausting the reducing gas from the process vessel;

removing the reducing gas remaining in the process vessel by supplying an inert gas into the process vessel and exhausting the inert gas from the process vessel;

after the reducing gas is removed from the process vessel, forming a nickel-containing film on the heated and pretreated substrate to a predetermined thickness by supplying a nickel-containing source into the process vessel and exhausting the nickel-containing source from the process vessel; and

unloading the substrate from the process vessel.

According to another aspect of the present invention, there is provided a substrate processing apparatus including:

a process vessel in which a substrate is processed;

a reducing gas supply system configured to supply a reducing gas into the process vessel;

an inert gas supply system configured to supply an inert gas into the process vessel:

a source supply system configured to supply a nickel-containing source into the process vessel;

an exhaust system configured to exhaust an inside of the process vessel;

a heater configured to heat the substrate in the process vessel; and

a control unit configured to control the reducing gas supply system, the inert gas supply system, the source supply system, the exhaust system, and the heater so as to: heat the substrate in the process vessel; pretreat the heated substrate by supplying the reducing gas into the process vessel and exhausting the reducing gas from the process vessel; remove the reducing gas remaining in the process vessel by supplying the inert gas into the process vessel and exhausting the inert gas from the process vessel; and form a nickel-containing film on the heated and pretreated substrate to a predetermined thickness by supplying the nickel-containing source into the process vessel and exhausting the nickel-containing source from the process vessel after the reducing gas is removed.

### BRIEF DESCRIPTION OF THE DRAWINGS

FIG. 1 is a flowchart for explaining substrate processing processes according to an embodiment of the present invention.

FIG. 2 is a view illustrating a gas supply system and an exhaust system of a substrate processing apparatus according to the embodiment of the present invention.

FIG. 3 is a sectional view illustrating the substrate processing apparatus when a wafer is processed according to the embodiment of the present invention.

FIG. 4 is a sectional view illustrating the substrate processing apparatus when a wafer is carried according to the embodiment of the present invention.

FIG. 5A and FIG. 5B are schematic views illustrating a vertical process furnace 302 of a vertical chemical vapor deposition (CVD) apparatus that can be suitably used according to another embodiment of the present invention, in which FIG. 5A is a vertical sectional view of the process furnace 302, and FIG. 5B is a sectional view of the process furnace 302 taken along line A-A of FIG. 5A.

FIG. 6 is a view illustrating the dependence of the resistivity of a Ni film on a pretreatment time when a pretreatment was performed to an evaluation sample wafer by using a reducing gas (H₂ gas or NH₃ gas) before the Ni film was formed on the wafer by a CVD method using Ni(PF₃)₄.

FIG. 7A to FIG. 7C are views (electron microscope images) illustrating the surface morphologies of Ni films for the case where a pretreatment was performed using a reducing gas (H₂ gas, NH₃ gas) and the case where a pretreatment was not performed.

FIG. 8 is a view illustrating the dependence of the P intensity of Ni film on a purge time after a pretreatment process.

FIG. 9A to FIG. 9C are views illustrating gas supply timing for preparing evaluation samples, in which FIG. 9A illustrates the case of supplying Ni(PF₃)₄ continuously, FIG. 9B illustrates the case where Ni(PF₃)₄ and N₂ are alternately supplied, and FIG. 9C illustrates the case where Ni(PF₃)₄ and H₂ are alternately supplied.

FIG. 10 is a view illustrating the P/Ni X-ray fluorescence intensity ratios of Ni films of evaluation samples.

FIG. 11A to FIG. 11C are views (electron microscope images) illustrating the surface morphologies of Ni films of evaluation samples.

### DETAILED DESCRIPTION OF THE PREFERRED EMBODIMENTS

### (1) Structure of Substrate Processing Apparatus

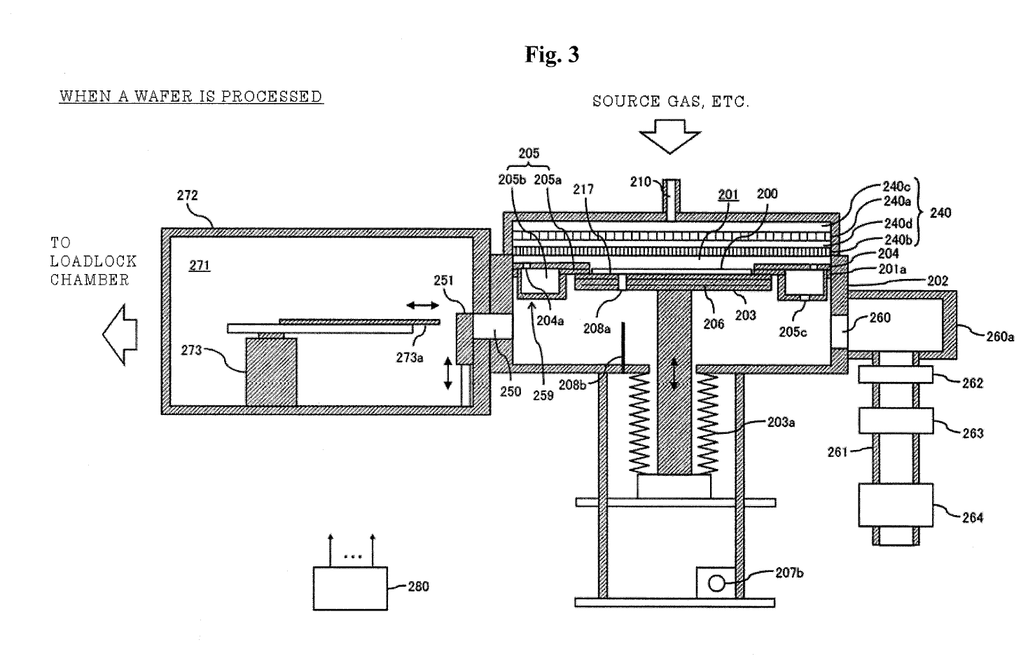

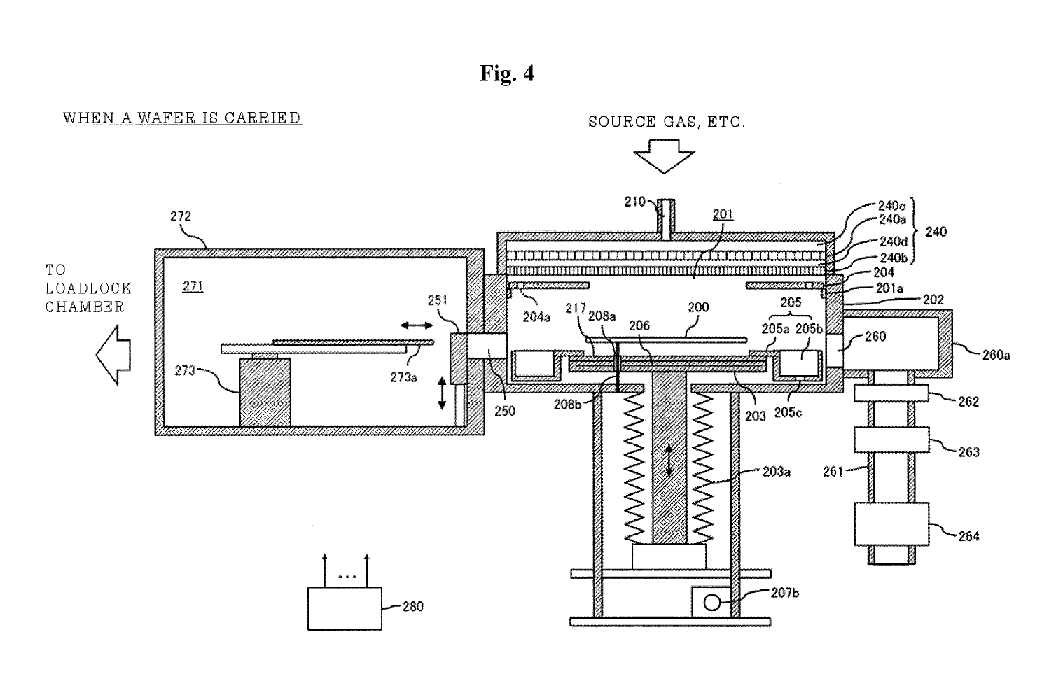

First, the structure of a substrate processing apparatus relevant to the current embodiments will be described with reference to FIG. 3 and FIG. 4. FIG. 3 is a sectional view illustrating the substrate processing apparatus when a wafer is processed according to an embodiment of the present invention, and FIG. 4 is a sectional view illustrating the substrate processing apparatus when the wafer is carried according to the embodiment of the present invention.

<Process Chamber>

As shown in FIG. 3 and FIG. 4, the substrate processing apparatus relevant to the current embodiments includes a process vessel 202. For example, the process vessel 202 is a flat airtight vessel having a circular cross sectional shape. In addition, the process vessel 202 is made of a metal material such as aluminum (Al) or stainless steel (such as SUS described in the Japanese industrial standard). In the process vessel 202, a process chamber 201 is formed to process a substrate such as a wafer 200 (e.g., a silicon wafer).

<Support Stage>

In the process chamber 201, a support stage 203 is installed to support a wafer 200. On the top surface of the support stage 203 that makes direct contact with the wafer 200, a susceptor 217 made of a material such as quartz (SiO₂), carbon, a ceramic material, silicon carbide (SiC), aluminum oxide (Al₂O₃), or aluminum nitride (AlN) is installed as a support plate. In the support stage 203, a heater 206 is built as a heating unit (heating source) configured to heat the wafer 200. The lower end part of the support stage 203 penetrates the bottom side of the process vessel 202.

<Elevating Mechanism>

At the outside of the process chamber 201, an elevating mechanism 207b is installed to raise and lower the support stage 203. By operating the elevating mechanism 207b to raise and lower the support stage 203, the wafer 200 supported on the susceptor 217 can be raised and lowered. When the wafer 200 is carried, the support stage 203 is lowered to a position (wafer carrying position) shown in FIG. 4, and when the wafer 200 is processed, the support stage 203 is raised to a position (wafer processing position) shown in FIG. 3. The lower end part of the support stage 203 is surrounded by a bellows 203a so that the inside of the process chamber 201 can be hermetically maintained.

<Lift Pins>

In addition, on the bottom surface (floor surface) of the process chamber 201, for example, three lift pins 208b are installed in a manner such that the lift pins 208b are vertically erected. Furthermore, in the support stage 203 (including the susceptor 217), penetration holes 208a are respectively formed at positions corresponding to the lift pins 208b so that the lift pins 208b can be inserted through the penetration holes 208a. Therefore, when the support stage 203 is lowered to the wafer carrying position, as shown in FIG. 4, upper parts of the lift pins 208b protrude from the top surface of the susceptor 217 so that the lift pins 208b can support the wafer 200 from the bottom side of the wafer 200. In addition, when the support stage 203 is raised to the wafer processing position, as shown in FIG. 3, the lift pins 208b are retracted from the top surface of the susceptor 217 so that the susceptor 217 can support the wafer 200 from the bottom side of the wafer 2. Since the lift pins 208b make direct contact with the wafer 200, it is preferable that the lift pins 208b are made of a material such as quartz or aluminum.

<Wafer Carrying Entrance>

At a side of the inner wall of the process chamber 201 (process vessel 202), a wafer carrying entrance 250 is installed so that a wafer 200 can be carried into and out of the process chamber 201 through wafer carrying entrance 250. At the wafer carrying entrance 250, a gate valve 251 is installed so that the inside of the process chamber 201 can communicate with the inside of a carrying chamber (preliminary chamber) 271 by opening the gate valve 251. The carrying chamber 271 is formed in a carrying vessel (airtight vessel) 272. In the carrying chamber 271, a carrying robot 273 is installed to carry a wafer 200. The carrying robot 273 includes a carrying arm 273a to support a wafer 200 when the wafer 200 is carried. In a state where the support stage 203 is lowered to the wafer carrying position, if the gate valve 251 is opened, a wafer 200 can be carried between the inside of the process chamber 201 and the inside of the carrying chamber 271 by using the carrying robot 273. A wafer 200 carried into the process chamber 201 is temporarily placed on the lift pins 208b as described above. In addition, at a side of the carrying chamber 271 opposite to the wafer carrying entrance 250, a loadlock chamber (not shown) is installed, and a wafer 200 can be carried between the inside of the loadlock chamber and the inside of the carrying chamber 271 by using the carrying robot 273. The loadlock chamber is used as a preliminary chamber to temporarily accommodate a non-processed or processed wafer 200.

<Exhaust System>

At a side of the inner wall of the process chamber 201 (process vessel 202) opposite to the wafer carrying entrance 250, an exhaust outlet 260 is installed for exhausting the inside atmosphere of the process chamber 201. An exhaust pipe 261 is connected to the exhaust outlet 260 through an exhaust chamber 260a, and at the exhaust pipe 261, a pressure regulator 262 such as an auto pressure controller (APC) configured to control the inside pressure of the process chamber 201, a source collection trap 263, and a vacuum pump 264 are sequentially connected in series. An exhaust system (exhaust line) is constituted mainly by the exhaust outlet 260, the exhaust chamber 260a, the exhaust pipe 261, the pressure regulator 262, the source collection trap 263, and the vacuum pump 264.

<Gas Entrance>

At the top surface (the ceiling wall) of a shower head 240 (described later) installed at an upper part of the process chamber 201, a gas inlet 210 is installed to introduce various gases into the process chamber 201. A gas supply system connected to the gas inlet 210 will be described later.

<Shower Head>

Between the gas inlet 210 and the process chamber 201, the shower head 240 is installed as a gas distributing mechanism. The shower head 240 includes a distributing plate 240a configured to distribute a gas introduced through the gas inlet 210, and a shower plate 240b configured to distribute the gas passing through the distributing plate 240a more uniformly and supply the gas to the surface of a wafer 200 placed on the support stage 203. A plurality of ventilation holes are formed in the distributing plate 240a and the shower plate 240b. The distributing plate 240a is disposed to face the top surface of the shower head 240 and the shower plate 240b, and the shower plate 240b is disposed to face the wafer 200 placed on the support stage 203. Spaces are formed between the top surface of the shower head 240 and the distributing plate 240a and between the distributing plate 240a and the shower plate 240b, respectively. The spaces function as a first buffer space (distributing chamber) 240c through which gas supplied through the gas inlet 210 is distributed and a second buffer space 240d through which gas passing through the distributing plate 240a is diffused.

<Exhaust Duct>

In the side surface of the inner wall of the process chamber 201, a stopper 201a is installed. The stopper 201a is configured to hold a conductance plate 204 at a position close to the wafer processing position. The conductance plate 204 is configured as a doughnut-shaped (ring-shaped) circular disk having an opening to accommodate the wafer 200 in its inner circumferential part. A plurality of discharge outlets 204a are formed in the outer circumferential part of the conductance plate 204 in a manner such that the discharge outlets 204a are arranged at predetermined intervals in the circumferential direction of the conductance plate 204. The discharge outlets 204a are discontinuously formed so that the outer circumferential part of the conductance plate 204 can support the inner circumferential part of the conductance plate 204.

A lower plate 205 latches onto the outer circumferential part of the support stage 203. The lower plate 205 includes a ring-shaped concave part 205b and a flange part 205a formed in one piece with the inner upper side of the concave part 205b. The concave part 205b is installed to close a gap between the outer circumferential part of the support stage 203 and the side surface of the inner wall of the process chamber 201. At a part of the lower side of the concave part 205b close to the exhaust outlet 260, a plate exhaust outlet 205c is formed to discharge (distribute) gas from the inside of the concave part 205b toward the exhaust outlet 260. The flange part 205a functions as a latching part that latches onto the upper outer circumferential part of the support stage 203. Since the flange part 205a latches onto the upper outer circumferential part of the support stage 203, the lower plate 205 can be lifted together with the support stage 203 when the support stage 203 is lifted.

When the support stage 203 is raised to the wafer processing position, the lower plate 205 is also raised to the wafer processing position. As a result, the top surface of the concave part 205b of the lower plate 205 is blocked by the conductance plate 204 held at a position close to the wafer processing position, and thus a gas flow passage region is formed in the concave part 205b as an exhaust duct 259. At this time, by the exhaust duct 259 (the conductance plate 204 and the lower plate 205) and the support stage 203, the inside of the process chamber 201 is divided into an upper process chamber higher than the exhaust duct 259 and a lower process chamber lower than the exhaust duct 259. Preferably, the conductance plate 204 and the lower plate 205 may be formed of a material that can be held at a high temperature, for example, high temperature resistant and high load resistant quartz, for the case where reaction products deposited on the inner wall of the exhaust duct 259 are etched away (for the case of self cleaning).

An explanation will now be given on a gas flow in the process chamber 201 during a wafer processing process. First, gas supplied from the gas inlet 210 to the upper side of the shower head 240 flows from the first buffer space (distributing chamber) 240c to the second buffer space 240d through the plurality of holes of the distributing plate 240a, and is then supplied to the inside of the process chamber 201 through the plurality of holes of the shower plate 240b, so that the gas can be uniformly supplied to the wafer 200. Then, the gas supplied to the wafer 200 flows outward in the radial directions of the wafer 200. After the gas makes contact with the wafer 200, remaining gas is discharged to the exhaust duct 259 disposed at the outer circumference of the wafer 200: that is, the remaining gas flows outward on the conductance plate 204 in the radial directions of the wafer 200 and is discharged to the gas flow passage region (the inside of the concave part 205b) of the exhaust duct 259 through the discharge outlets 204a formed in the conductance plate 204. Thereafter, the gas flows in the exhaust duct 259 and is exhaust through the plate exhaust outlet 205c and the exhaust outlet 260. Since gas is directed to flow in this manner, the gas may be prevented from flowing to the lower part of the process chamber 201. That is, the gas may be prevented from flowing to the rear side of the support stage 203 or the bottom side of the process chamber 201.

<Gas Supply System)

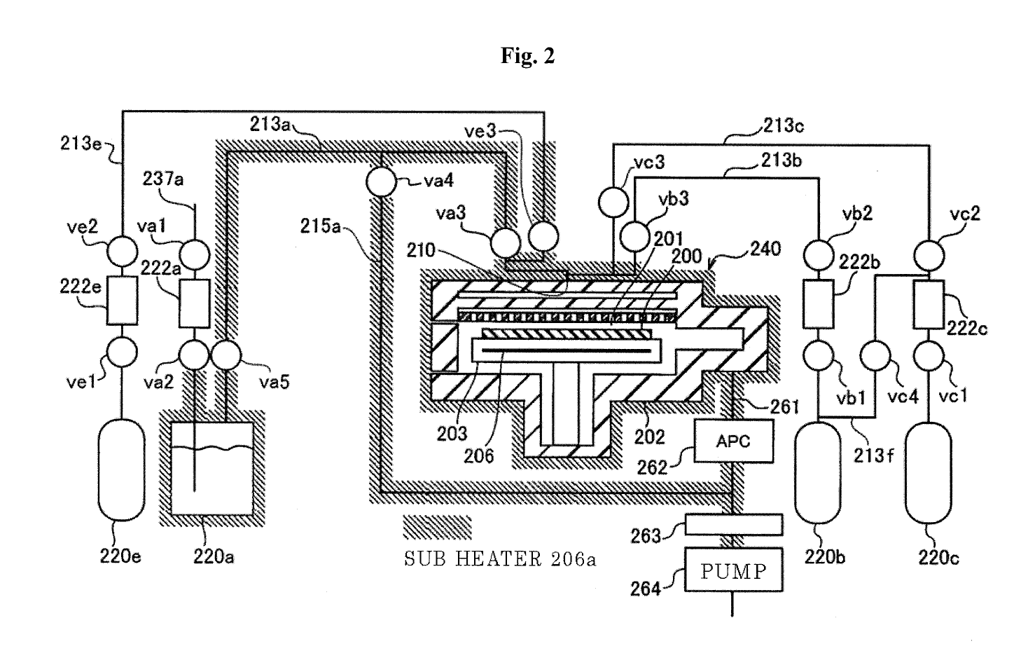

Next, the configuration of the gas supply system connected to the gas inlet 210 will be described with reference to FIG. 2. FIG. 2 is a view illustrating the gas supply system and the exhaust system of the substrate processing apparatus according to the embodiment of the present invention.

The gas supply system of the substrate processing apparatus of the current embodiment includes: a bubbler 220a as a vaporizing unit configured to vaporize a liquid source containing nickel (Ni) which is liquid at room temperature; a source gas supply system configured to supply a source gas, obtained by vaporizing the liquid source using the bubbler 220a, into the process chamber 201; a reducing gas supply system configured to supply a reducing gas into the process chamber 201; and a purge gas supply system configured to supply a purge gas into the process chamber 201. In addition, the substrate processing apparatus of the current embodiment includes a vent (bypass) system so as not to supply a source gas generated from the bubbler 220a into the process chamber 201 but to exhaust the source gas through a passage bypassing the process chamber 201. Next, the structure of each part will be described.

<Bubbler>

At the outside of the process chamber 201, the bubbler 220a is installed as a source container configured to store a liquid source. The bubbler 220a is configured as a tank (airtight container) in which a liquid source can be stored (filled). In addition, the bubbler 220 functions as a vaporizing unit capable of generating a source gas by vaporizing a liquid source through bubbling. In addition, a sub heater 206a is installed around the bubbler 220a to heat the bubbler 220a and a liquid source filled in the bubbler 220a. For example, a liquid metal source containing nickel (Ni) such as tetrakis(trifluorophosphine)nickel (Ni(PF₃)₄) may be used as a source.

A carrier gas supply pipe 237a is connected to the bubbler 220a. A carrier gas supply source (not shown) is connected to the end part of the upstream side of the carrier gas supply pipe 237a. In addition, the end part of the downstream side of the carrier gas supply pipe 237a is placed in a liquid source filled in the bubbler 220a. A mass flow controller (MFC) 222a which is a flow rate controller configured to control the supply flow rate of a carrier gas, and valves va1 and va2 configured to control supply of carrier gas are installed at the carrier gas supply pipe 237a. Preferably, a gas that does not react with the liquid source may be used as a carrier gas. For example, inert gas such as N₂ gas, Ar gas, and He gas may be used as a carrier gas. A carrier gas supply system (carrier gas supply line) is constituted mainly by the carrier gas supply pipe 237a, the MFC 222a, and the valves va1 and va2.

In the above-described structure, the valves va1 and va2 are opened, and a carrier gas the flow rate of which is controlled by the MFC 222a is supplied from the carrier gas supply pipe 237a into the bubbler 220a. Then, the liquid source filled in the bubbler 220a is vaporized by bubbling, and thus a source gas is generated.

<Source Gas Supply System>

A source gas supply pipe 213a is connected to the bubbler 220a to supply a source gas generated in the bubbler 220a to the inside of the process chamber 201. The end part of the upstream side of the source gas supply pipe 213a communicates with an inner upper space of the bubbler 220a. The end part of the downstream side of the source gas supply pipe 213a is connected to the gas inlet 210. Valves va5 and va3 are sequentially installed from the upstream side of the source gas supply pipe 213a. The valve va5 is configured to control supply of a source gas from the bubbler 220a to the source gas supply pipe 213a, and the valve va5 is installed at a position close to the bubbler 220a. The valve va3 is configured to control supply of a source gas from the source gas supply pipe 213a to the process chamber 201, and the valve va3 is installed at a position close to the gas inlet 210. The valve va3 and a valve ve3 (described later) are highly-durable, high-speed valves. Highly-durable, high-speed valves are integrated valves configured to rapidly switch gas supply and exhaust gas. The valve ve3 is configured to control introduction of a purge gas for rapidly purging a space of the source gas supply pipe 213a between the valve va3 and the gas inlet 210 and then purging the inside of the process chamber 201.

In the above-described structure, the liquid source is vaporized to generate a source gas, and the valves va5 and va3 are simultaneously opened. Then, the source gas can be supplied from the source gas supply pipe 213a to the inside of the process chamber 201. The source gas supply system (source gas supply line) is constituted mainly by the source gas supply pipe 213a and the valves va5 and va3.

In addition, a source supply system (source supply line) is constituted mainly by the carrier gas supply system, the bubbler 220a, and the source gas supply system.

<Reducing Gas Supply System>

In addition, at the outside of the process chamber 201, a reducing gas supply source 220b is installed to supply a reducing gas. The upstream end part of a reducing gas supply pipe 213b is connected to the reducing gas supply source 220b. The downstream end part of the reducing gas supply pipe 213b is connected to the gas inlet 210 through a valve vb3. A MFC 222b which is a flow rate controller configured to control the supply flow rate of a reducing gas, and valves vb1, vb2, and vb3 configured to control supply of a reducing gas are installed at the reducing gas supply pipe 213b. Hydrogen-containing gas may be used as a reducing gas. For example, in the current embodiment, hydrogen (H₂) gas or ammonia (NH₃) gas may be used as a reducing gas. That is, in the current embodiment, the reducing gas supply source 220b is configured to as a hydrogen-containing gas supply source. A reducing gas supply system (reducing gas supply line), that is, a hydrogen-containing gas supply system (hydrogen-containing gas supply line) is constituted mainly by the reducing gas supply source 220b, the reducing gas supply pipe 213b, the MFC 222b, and the valves vb1, vb2, and vb3.

<Purge Gas Supply System>

In addition, at the outside of the process chamber 201, purge gas supply sources 220c and 220e are installed to supply purge gas. The upstream end parts of purge gas supply pipes 213c and 213e are connected to the purge gas supply sources 220c and 220e, respectively. The downstream end part of the purge gas supply pipe 213c is connected to the gas inlet 210 through a valve vc3. The downstream end part of the purge gas supply pipe 213e is jointed to a part of the source gas supply pipe 213a between the valve va3 and the gas inlet 210 and is then connected to the gas inlet 210. At the purge gas supply pipes 213c and 213e, MFCs 222c and 222e are respectively installed as flow rate controllers configured to control the supply flow rates of purge gas, and valves vc1, vc2, vc3, ve1, ve2, and ve3 are respectively installed to control supply of purge gas. In addition, for a maintenance work, a purge gas supply pipe 213f is connected the reducing gas supply pipe 213b between the reducing gas supply source 220b and the valve vb1. The purge gas supply pipe 213f branches off from the purge gas supply pipe 213c between the MFC 222c and the valve vc2. For example, inert gas such as N₂ gas, Ar gas, and He gas may be used as a purge gas. A purge gas supply system (purge gas supply line) is constituted mainly by the purge gas supply sources 220c and 220e, the purge gas supply pipes 213c, 213e, 213f, the MFCs 222c and 222e, the valves vc1, vc2, vc3, vc4, ve1, ve2, and ve3.

<Vent (Bypass) System>

Furthermore, the upstream end part of a vent pipe 215a is connected to the upstream side of the valve va3 of the source gas supply pipe 213a. In addition, the downstream end part of the vent pipe 215a is connected between the downstream side of the pressure regulator 262 and the upstream side of the source collection trap 263 of the exhaust pipe 261. At the vent pipe 215a, a valve va4 is installed to control flows of gas.

In the above-described structure, if the valve va3 is closed and the valve va4 is opened, gas flowing in the source gas supply pipe 213a can bypass the process chamber 201 and be exhausted to the exhaust pipe 261 through the vent pipe 215a without being supplied to the process chamber 201. A vent (bypass) system is constituted mainly by the vent pipe 215a and the valve va4.

The sub heater 206a is installed around the bubbler 220a as described above, and in addition to this, the sub heater 206a is also installed around the carrier gas supply pipe 237a, the source gas supply pipe 213a, the purge gas supply pipe 213e, the vent pipe 215a, the exhaust pipe 261, the process vessel 202, and the shower head 240. The sub heater 206a is configured to heat such members to, for example, 100° C. or lower, so as to prevent a source gas from changing back to liquid in the members.

<Control Unit>

The substrate processing apparatus relevant to the current embodiment includes a controller 280 configured to control each part of the substrate processing apparatus. The controller 280 controls operations of parts such as the gate valve 251, the elevating mechanism 207b, the carrying robot 273, the heater 206, the sub heater 206a, the pressure regulator (APC) 262, the vacuum pump 264, the valves va1 to va5, vb1 to vb3, vc1 to vc4, and ve1 to ve3, the MFCs 222a, 222b, 222c, and 222e.

### (2) Substrate Processing Process

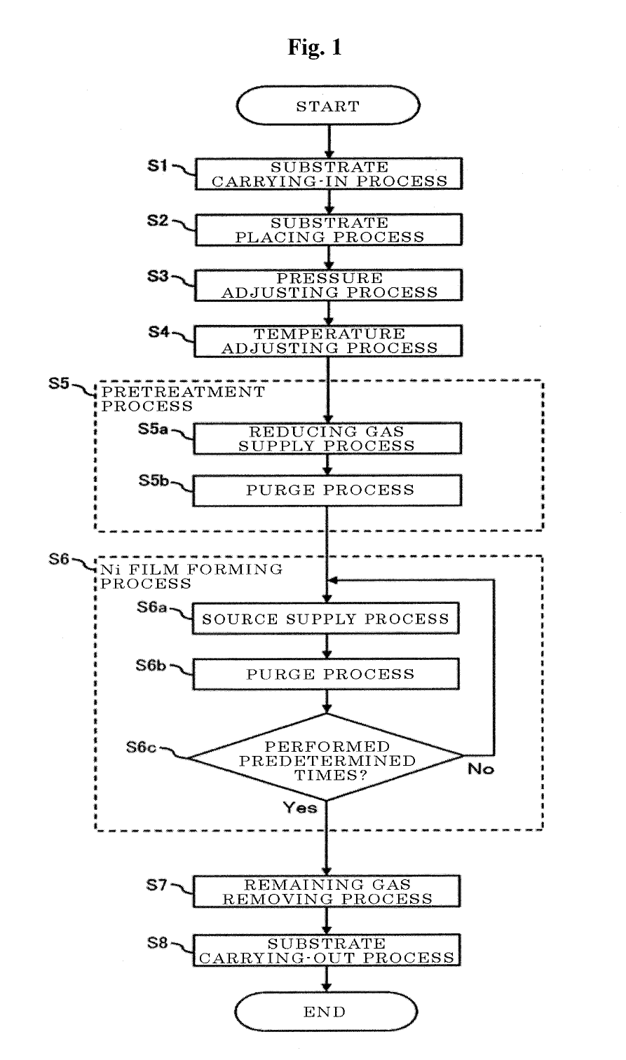

Next, with reference to FIG. 1, an explanation will be given on one of semiconductor device manufacturing processes, that is, a substrate processing process for forming a metal film on a wafer using the above-described process vessel 202 of the substrate processing apparatus. FIG. 1 is a flowchart for explaining substrate processing processes according to the embodiment of the present invention. In the following description, the controller 280 controls parts of the substrate processing apparatus.

In the following description, explanations will be given on exemplary processes such as: a process of performing a pretreatment to a substrate such as a wafer by supplying a reducing gas such as H₂ gas or NH₃ gas into the process vessel 202 and exhausting the reducing gas from the process vessel 202 in a state where the wafer is loaded into the processing vessel 202 and heated in the processing vessel 202; a process of removing the reducing gas remaining in the process vessel 202 by supplying an inert gas such as N₂ gas into the process vessel 202 and exhausting the inert gas from the process vessel 202; and a process of forming a nickel film (Ni film) as a nickel-containing metal film on the heated and pretreated wafer by supplying a nickel (Ni)-containing source such as Ni(PF₃)₄ into the process vessel 202 and exhausting the Ni(PF₃)₄ from the process vessel 202. In the Ni film forming process, a process of forming a Ni film on the heated and pretreated wafer by supplying Ni(PF₃)₄ into the process vessel 202 and exhausting the Ni(PF₃)₄ from the process vessel 202, and a process of purging the inside of the process vessel 202 by supplying an inert gas such as N₂ gas into the process vessel 202 and exhausting the N₂ gas from the process vessel 202 may be set as one cycle, and the cycle may be performed predetermined times to form a Ni film on the pretreated (reduction-treated) wafer to a predetermined thickness by a chemical vapor deposition (CVD) method. In the following description, this example will be explained.

In this specification, the term “metal film” is used to denote a film formed of a conductive material containing metal atoms. Examples thereof include a conductive elemental metal film formed of an elemental metal, a conductive metal nitride film, a conductive metal oxide film, a conductive metal oxynitride film, a conductive metal composite film, a conductive metal alloy film, and a conductive metal silicide film. A Ni film is an example of the conductive elemental metal film formed of an elemental metal. This will now be explained in detail.

<Substrate Carrying-in Process S1, Substrate Placing Process S2>

First, the elevating mechanism 207b is operated to lower the support stage 203 to the wafer carrying position as shown in FIG. 4. Next, the gate valve 251 is opened so that the process chamber 201 can communicate with the carrying chamber 271. Next, a wafer 200 to be processed is carried from the carrying chamber 271 to the process chamber 201 by using the carrying robot 273 in a state where the wafer 200 is supported on the carrying arm 273a (S1). The wafer 200 loaded in the process chamber 201 is temporarily placed on the lift pins 208b which protrudes upward from the top surface of the support stage 203. Thereafter, the carrying arm 273a of the carrying robot 273 is moved back to the carrying chamber 271, and the gate valve 251 is closed.

Next, the elevating mechanism 207b is operated to raise the support stage 203 to the wafer processing position as shown in FIG. 3. As a result, the lift pins 208b are retracted from the top surface of the support stage 203, and the wafer 200 is placed on the susceptor 217 disposed at the top surface of the support stage 203.

<Pressure Adjusting Process S3, Temperature Adjusting Process S4)

Subsequently, by using the pressure regulator (APC) 262, the inside pressure of the process chamber 201 is adjusted to a predetermined process pressure (S3). In addition, power supplied to the heater 206 is controlled to increase the surface temperature of the wafer 200 to a predetermined process temperature (S4). The temperature adjusting process S4 may be performed in parallel with or prior to the process adjusting process S3. The predetermined process temperature and process pressure are set in a manner such that a Ni film can be formed in a source supply process (described later) by a CVD method. That is, a source used in the source supply process may decompose at the predetermined process temperature and process pressure. Furthermore, in a reducing gas supply process (described later), a pretreatment may be performed to the wafer 200 at the process temperature and process pressure by using a reducing gas.

In the substrate carrying-in process S1, the substrate placing process S2, the pressure adjusting process S3, and the temperature adjusting process S4, the vacuum pump 264 is operated in a state where the valves va3 and vb3 are closed and the valves vc1, vc2, vc3, ve1, ve2, and ve3 are opened, so as to create a flow of N₂ gas in the process chamber 201. By this, adhesion of particles to the wafer 200 can be suppressed.

<Pretreatment Process S5>

[Reducing Gas Supply Process S5a]

Next, while operating the vacuum pump 264, the valves vb1, vb2, and vb3 are opened to supply a reducing gas such as H₂ gas or NH₃ gas into the process chamber 201. The reducing gas is distributed by the shower head 240 and uniformly supplied to the wafer 200 disposed in the process chamber 201. Surplus reducing gas flows in the exhaust duct 259 and is exhausted to the exhaust outlet 260 and the exhaust pipe 261. In this way, the wafer 200 is pretreated by the reducing gas supplied to the wafer 200.

When the reducing gas is supplied into the process chamber 201, so as to prevent permeation of the reducing gas into the source gas supply pipe 213a and facilitate diffusion of the reducing gas in the process chamber 201, it is preferable that the valves ve1, ve2, and ve3 are kept in an opened state to continuously supply N₂ gas into the process chamber 201.

After a predetermined time from the start of supply of the reducing gas by opening the valve vb1, vb2, and vb3, the supply of the reducing gas into the process chamber 201 is interrupted by closing the valves vb1, vb2, and vb3. After that, in a state where a valve (not shown) installed at the reducing gas supply source 220b is closed, the valves vc1, vc4, vb1, vb2, and vb3 are opened so as to purge the inside of the reducing gas supply pipe 213b by supplying N₂ gas into the reducing gas supply pipe 213b.

[Purge Process S5b]

Thereafter, the process chamber 201 is vacuum-evacuated, and the valves vc1, vc2, vc3, ve1, ve2, and ve3 are opened to supply N₂ gas into the process chamber 201. The N₂ gas is dispersed by the shower head 240 and supplied into the process chamber 201, and then the N₂ gas flows in the exhaust duct 259 where the N₂ gas is exhausted to the exhaust outlet 260 and the exhaust pipe 261. In this way, reducing gas and reaction byproducts remaining in the process chamber 201 are removed, and the inside of the process chamber 201 is purged by the N₂ gas. This purge process S5b may be omitted. In this case, however, in a source supply process S6a (described later), the reducing gas is mixed with a source (Ni(PF₃)₄) gas in the process chamber 201, and thus Ni(PF₃)₄ decomposes excessively. Accordingly, phosphorus (P) of Ni(PF₃)₄ easily permeates a Ni film, and the P concentration of the Ni film increases. Therefore, in the case of using a source such as Ni(PF₃)₄ that easily reacts with a reducing gas (H₂ gas or NH₃ gas), the purge process S5b may not be omitted. That is, the purge process S5b may be essential to reducing the impurity concentration (P concentration) of a Ni film.

Along with processes S1 to S5, a source (Ni(PF₃)₄) is vaporized to generate a source gas (preliminary vaporization). That is, the valves va1, va2, and va5 are opened, and a carrier gas the flow rate of which is controlled by the MFC 222a is supplied from the carrier gas supply pipe 237a into the bubbler 220a so as to vaporize a liquid source filled in the bubbler 220a by bubbling so as to generate a source gas (preliminary vaporization process). In this preliminary vaporization process, while operating the vacuum pump 264, the valve va4 is opened in a state where the valve va3 is closed, so that the source gas is not supplied into to the process chamber 201 but is exhausted through a route bypassing the process chamber 201. A predetermined time is necessary for the bubbler 220a to stably generate a source gas. For this reason, in the current embodiment, a source gas is preliminary generated, and the flow passage of the source gas is changed by selectively opening and closing the valves va3 and va4. That is, by selectively opening and closing the valves va3 and va4, stable supply of the source gas into the process chamber 201 can be quickly started and stopped. This operation is preferable.

<Ni Film Forming Process S6>

[Source Supply Process S6a]

Next, while operating the vacuum pump 264, the valve va4 is closed and the valve va3 is opened to supply a source gas (Ni source) into the process chamber 201. The source gas is dispersed by the shower head 240 so that the source gas can be uniformly supplied to the wafer 200 disposed in the process chamber 201. Surplus source gas flows in the exhaust duct 259 and is exhausted to the exhaust outlet 260 and the exhaust pipe 261. At this time, the process temperature and process pressure are set in a manner such that the source gas can decompose. Therefore, the source gas supplied to the wafer 200 thermally decomposes and participates in a CVD reaction, and accordingly a Ni film is formed on the wafer 200 which is pretreated by using a reducing gas.

When the source gas is supplied into the process chamber 201, so as to prevent permeation of the source gas into the reducing gas supply pipe 213b and facilitate diffusion of the source gas in the process chamber 201, it is preferable that the valves vc1, vc2, and vc3 are kept in an opened state to continuously supply N₂ gas into the process chamber 201.

After a predetermined time from the start of supply of the source gas through the valve va3, the valve va3 is closed, and the valve va4 is opened to stop supply of the source gas into the process chamber 201.

[Purge process S6b]

After stopping supply of the source gas by closing the valve va3, the valves vc1, vc2, vc3, ve1, ve2, and ve3 are opened to supply N₂ gas into the process chamber 201. The N₂ gas is dispersed by the shower head 240 and supplied into the process chamber 201, and then the N₂ gas flows in the exhaust duct 259 where the N₂ gas is exhausted to the exhaust outlet 260 and the exhaust pipe 261. In this way, source gas and reaction byproducts remaining in the process chamber 201 are removed, and the inside of the process chamber 201 is purged by the N₂ gas.

[N-Time Executing Process S6c]

The source gas supply process S6a and the purge process S6b are set as one cycle, and the cycle is performed predetermined times to form a nickel film (Ni film) having a predetermined thickness on the pretreated wafer 200. Furthermore, in the current embodiment, a source may be supplied in a pulsed manner or continuously. The latter case (continuous supply of a source) corresponds to a one-time execution of the cycle of the source supply process S6a and the purge process S6b.

[Remaining Gas Removing Process S7]

After a Ni film having a predetermined thickness is formed on the wafer 200, the process chamber 201 is vacuum-evacuated, and the valves vc1, vc2, vc3, ve1 ve2, and ve3 are opened to supply N₂ gas into the process chamber 201. The N₂ gas is dispersed by the shower head 240 and supplied into the process chamber 201, and then the N₂ gas flows in the exhaust duct 259 where the N₂ gas is exhausted to the exhaust outlet 260 and the exhaust pipe 261. In this way, gases and reaction byproducts remaining in the process chamber 201 are removed, and the inside of the process chamber 201 is purged by the N₂ gas.

<Substrate Carrying-Out Process S7>

Thereafter, in the reverse order to that of the substrate carrying-in process S1 and the substrate placing process S2, the wafer 200, on which the Ni film is formed to a predetermined thickness, is carried out from the process chamber 201 to the carrying chamber 271, thereby completing the substrate processing process of the current embodiment. Furthermore, in a nickel silicide (NiSi) process, for example, the wafer 200 on which the Ni film is formed to a predetermined thickness is carried to an annealing apparatus to anneal the wafer 200 under an inert atmosphere to cause a solid-phase reaction between the Ni film and Si (wafer 200) laying under the Ni film so as to form a NiSi film.

In the current embodiment, the pretreatment process S5 may be performed on a wafer 200 by using a reducing gas under the following exemplary conditions:

Process temperature (wafer temperature): 150° C. to 250° C.,

Process pressure (pressure in the process chamber): 50 Pa to 5,000 Pa,

Supply flow rate of reducing gas (H₂ gas or NH₃ gas): 50 sccm to 1,000 sccm,

Supply time of reducing gas (H₂ gas or NH₃ gas): 10 seconds to 600 seconds, and

Supply flow rate of purge gas (N₂): 10 sccm to 10,000 sccm.

Furthermore, in the current embodiment, the Ni film forming process S6 may be performed on a wafer 200 under the following exemplary conditions.

Process temperature (wafer temperature): 150° C. to 250° C.,

Process pressure (pressure in the process chamber): 50 Pa to 5,000 Pa,

Supply flow rate of carrier gas for bubbling: 10 sccm to 1,000 sccm,

Supply flow rate of nickel source (Ni(PF₃)₄): 0.1 sccm to 2 sccm,

Supply flow rate of purge gas (N₂): 10 sccm to 10,000 sccm.

Supply time of source (Ni(PF₃)₄) per cycle: 0.1 seconds to 600 seconds,

Purge time per cycle: 0.1 seconds to 600 seconds,

Number of cycles: 1 to 400 times, and

Ni film thickness: 10 nm to 30 nm.

If the process temperature is lower than 150° C. although the process pressure is kept in the above-mentioned range, a source (Ni(PF₃)₄) does not decomposes and a CVD film forming reaction does not occur in the source supply process S6a. In addition, if the process temperature is higher than 250° C. although the process pressure is kept in the above-mentioned range, the film forming rate increases excessively, and thus it is difficult to control the thickness of a film. Therefore, in the source supply process S6a, it is necessary to keep the process temperature in the range from 150° C. to 250° C. for inducing a CVD film forming reaction and controlling the thickness of a film. In the above-mentioned ranges of the process pressure and process temperature, a wafer 200 can be pretreated through the reducing gas supply process S5a. Therefore, in the current embodiment, the pretreatment process S5 and the Ni film forming process S6 are performed in the same process temperature range and the same process pressure range. Owing to this, a process of changing the process temperature or the process pressure is not necessary between the pretreatment process S5 and the Ni film forming process S6, and thus throughput, that is, productivity can be improved. For improving productivity, it is important that the pretreatment process S5 and the Ni film forming process S6 are performed in the same process temperature range. However, although the process pressure is changed, influence on the productivity is small. Therefore, the pretreatment process S5 may be performed in a pressure range optimal to a reducing treatment.

In the current embodiment, before the Ni film forming process S6, a wafer 200 is pretreated by using a reducing gas in the pretreatment process S5, so that adhesion of Ni to the surface of the wafer 200 can be facilitated and initial nucleation density can be increased in the Ni film forming process S6. As a result, a continuous film (low-resistance film) can be formed in a thin-film region, and a high-quality Ni film having a good surface morphology can be formed. In addition, owing to the reducing treatment in the pretreatment process S5, the grain size of a Ni film can be controlled as well as the grain density of the Ni film. Furthermore, a high-quality Ni film having good step coverage and adhesiveness can be formed.

In the above-described embodiment, an explanation has been given on an exemplary case of forming a Ni film as a Ni-containing film. Examples of a Ni-containing film include a Ni film, a NiₓSi_{y} film, and a NiₓO_{y} film (where x denotes an integer or a fraction, and y denotes an integer or a fraction). The present invention can be also applied to the case where the Ni-containing film is any of the above-mentioned films.

In the above-described embodiment, the pretreatment process S5 is performed after the temperature adjusting process S4. However, the pretreatment process S5 may be started before the temperature adjusting process S4 is completed. That is, the reducing gas supply process S5a may be started while the temperature of a wafer 200 is increased. This may advance the completion time of the pretreatment process S5, and thus the throughput of the substrate processing process can be improved.

<Another Embodiment of Invention>

In the above-described embodiment, an explanation has been given on an exemplary case of forming a film by using a single wafer type CVD apparatus which is a substrate processing apparatus (film-forming apparatus) configured to process substrates one by one. However, the present invention is not limited thereto. For example, a film-forming process may be performed by using a substrate processing apparatus such as a batch type vertical CVD apparatus configured to process a plurality of substrates at a time. Hereinafter, such a vertical CVD apparatus will be described.

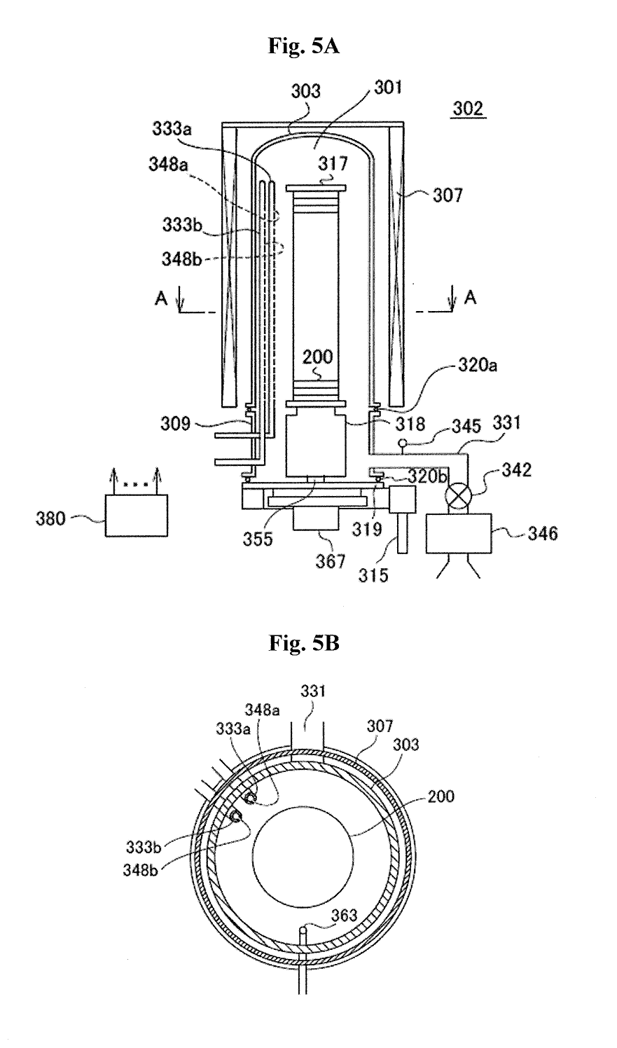

FIG. 5A and FIG. 5B are schematic views illustrating a vertical process furnace 302 of a vertical CVD apparatus that can be suitably used according to the current embodiment, in which FIG. 5A is a vertical sectional view of the process furnace 302, and FIG. 5B is a sectional view of the process furnace 302 taken along line A-A of FIG. 5A.

As shown in FIG. 5A, the process furnace 302 includes a heater 307 as a heating unit (heating mechanism). The heater 307 has a cylindrical shape and is supported on a holding plate such as a heater base so that the heater 307 can be vertically fixed.

Inside the heater 307, a process tube 303 is installed concentrically with the heater 307 as a reaction tube. The process tube 303 is made of a heat-resistant material such as quartz (SiO₂) and silicon carbide (SiC) and has a cylindrical shape with a closed top side and an opened bottom side. In the hollow part of the process tube 303, a process chamber 301 is formed, which is configured to accommodate substrates such as wafers 200 in a state where the wafers 200 are horizontally positioned and vertically arranged in multiple stages in a boat 317 (described later).

At the lower side of the process tube 303, a manifold 309 is installed concentrically with the process tube 303. The manifold 309 is made of a material such as stainless steel and has a cylindrical shape with opened top and bottom sides. The manifold 309 is engaged with the process tube 303 and installed to support the process tube 303. Between the manifold 309 and the process tube 303, an O-ring 320a is installed as a seal member. The manifold 309 is supported by the heater base such that the process tube 303 can be vertically fixed. The process tube 303 and the manifold 309 constitute a reaction vessel.

A first nozzle 333a as a first gas introducing part, and a second nozzle 333b as a second gas introducing part are connected to the manifold 309 in a manner such that the first and second nozzles 333a and 333b penetrate the sidewall of the manifold 309. Each of the first and second nozzles 333a and 333b has an L-shape with a horizontal part and a vertical part. The horizontal part is connected to the manifold 309, and the vertical part is erected in an arc-shaped space between the inner wall of the process tube 303 and the wafers 200 along the inner wall of the process tube 303 from the lower side to the upper side in the arranged direction of the wafers 2. In the lateral sides of the vertical parts of the first and second nozzles 333a and 333b, first gas supply holes 348a and second gas supply holes 348b are formed, respectively. The first and second gas supply holes 348a and 348b have the same size and are arranged at the same pitch from the lower side to the upper side.

The same gas supply systems as those explained in the previous embodiment are connected to the first and second nozzles 333a and 333b. However, the current embodiment is different from the previous embodiments, in that the source gas supply system is connected to the first nozzle 333a and the reducing gas supply system is connected to the second nozzle 333b. In the current embodiment, a source gas and a reducing gas are supplied through different nozzles. Alternatively, the source gas and the reducing gas may be supplied through the same nozzle.

At the manifold 309, an exhaust pipe 331 is installed to exhaust the inside atmosphere of the process chamber 301. A vacuum exhaust device such as a vacuum pump 346 is connected to the exhaust pipe 331 through a pressure detector such a pressure sensor 345 and a pressure regulator such as an auto pressure controller (APC) valve 342, and based on pressure information detected by the pressure sensor 345, the APC valve 342 is controlled so that the inside of the process chamber 301 can be vacuum-evacuated to a predetermined pressure (vacuum degree). The APC valve 342 is an on-off valve configured to be opened and closed to start and stop vacuum evacuation of the inside of the process chamber 301, and configured to be adjusted in valve opening degree for adjusting the inside pressure of the process chamber 301.

At the lower side of the manifold 309, a seal cap 319 is installed as a furnace port cover capable of hermetically closing the opened bottom side of the manifold 309. The seal cap 319 is configured to be brought into contact with the manifold 309 in a vertical direction from the bottom side of the manifold 309. The seal cap 319 is made of a metal such as stainless steel and has a circular disk shape. On the top surface of the seal cap 319, an O-ring 320b is installed as a seal member configured to make contact with the bottom side of the manifold 309. At a side of the seal cap 319 opposite to the process chamber 301, a rotary mechanism 367 is installed to rotate the boat 317 (described later). A rotation shaft 355 of the rotary mechanism 367 is inserted through the seal cap 319 and is connected to the boat 317, so as to rotate the wafers 200 by rotating the boat 317. The seal cap 319 is configured to be vertically moved by a boat elevator 315 which is disposed at the outside of the process tube 303 as an elevating mechanism, and by this, the boat 317 can be loaded into and out of the process chamber 301.

The boat 317 which is a substrate holding tool is made of a heat-resistant material such as quartz or silicon carbide and is configured to hold a plurality of wafers 200 in a state where the wafers 200 are horizontally positioned and arranged in multiple stages with the centers of the wafers 200 being aligned. At the lower part of the boat 317, an insulating member 318 made of a heat-resistant material such as quartz or silicon carbide is installed to prevent heat transfer from the heater 307 to the seal cap 319. In the process tube 303, a temperature sensor 363 is installed as a temperature detector, and based on temperature information detected by the temperature sensor 363, power supplied to the heater 307 is controlled to obtain a desired temperature distribution in the process chamber 301. Like the first nozzle 333a and the second nozzle 333b, the temperature sensor 363 is installed along the inner wall of the process tube 303.

A controller 380 which is a control unit (control part) is configured to control operations of parts such as the APC valve 342, the heater 307, the temperature sensor 363, the vacuum pump 346, the rotary mechanism 367, the boat elevator 315, the valves va1 to va5, vb1 to vb3, vc1 to vc4, and ve1 to ve3, and the MFCs 222a, 222b, 222c, 222d, and 222e.

Next, an explanation will be given on a substrate processing process which is one of semiconductor device manufacturing processes for forming a metal film on a wafer 200 by a CVD method using the above-described process furnace 302 of the vertical CVD apparatus. In the following description, each part of the vertical CVD apparatus is controlled by the controller 380.

A plurality of wafers 200 are charged into the boat 317 (wafer charging). Then, as shown in FIG. 5A, the boat 317 in which the plurality of wafers 200 are held is lifted and loaded into the process chamber 301 by the boat elevator 315 (boat loading). In this state, the bottom side of the manifold 309 is sealed by the seal cap 319 with the O-ring 320b being disposed therebetween.

The inside of the process chamber 301 is vacuum-evacuated to a desired pressure (vacuum degree) by the vacuum pump 346. At this time, the inside pressure of the process chamber 301 is measured by the pressure sensor 345, and based on the measured pressure, the APC valve 342 is feedback-controlled. In addition, the inside of the process chamber 301 is heated to a desired temperature by the heater 307. At this time, so as to obtain a desired temperature distribution in the process chamber 301, power supplied to the heater 307 is feedback-controlled based on temperature information detected by the temperature sensor 363. Then, the rotary mechanism 367 rotates the boat 317 to rotate the wafers 200.

Thereafter, a pretreatment process and a Ni film forming process are performed in the same orders as those of the pretreatment process S5 and the Ni film forming process S6 described in the previous embodiment. That is, first, the heated wafers 200 are pretreated in a process S5a by supplying a reducing gas such as H₂ gas or NH₃ gas into the process chamber 301 and exhausting the reducing gas from the process chamber 301, and the reducing gas remaining in the process chamber 301 is removed in a process S5b by supplying an inert gas such as N₂ gas into the process chamber 301 and exhausting the inert gas from the process chamber 301. Thereafter, a cycle is set so that the cycle includes: a process S6a of forming Ni films on the heated and pretreated wafers 200 by supplying a source such as Ni(PF₃)₄ into the process chamber 301 and exhausting the source from the process chamber 301 after the reducing gas is removed from the process chamber 301; and a process S6b of purging the inside of the process chamber 301 by supplying an inert gas such as N₂ gas into the process chamber 301 and exhausting the inert gas from the process chamber 301. The cycle is performed predetermined times (process S6c) to form Ni films on the pretreated (reduction-treated) wafers 200 to a predetermined thickness by a CVD method. After the Ni films are formed on the wafers 200 to a predetermined thickness, a remaining gas removing process is performed in the same order as that of the remaining gas removing process S7 of the previous embodiment.

After that, the boat elevator 315 lowers the seal cap 319 to open the bottom side of the manifold 309 and unload the boat 317 from the process tube 303 through the opened bottom side of the manifold 309 in a state where the wafers 200 on which the Ni films are formed to a predetermined thickness are held in the boat 317 (boat unloading). Thereafter, the processed wafers 200 are discharged from the boat 317 (wafer discharging).

<Another Embodiment of the Invention>

As described above, if a reducing gas and a source (Ni(PF₃)₄) are mixed, the Ni(PF₃)₄ decomposes excessively, and thus phosphorus (P) of the Ni(PF₃)₄ easily permeates a Ni film to increase the P concentration of the Ni film increases. Thus, in the above-described embodiments, the inside of the process chamber is purged after supplying a reducing gas but before supplying a source, so as not to mix the reducing gas and the source for reducing the P concentration in a Ni film.

Alternatively, the P concentration of a Ni film may be reduced by using a method different from that explained in the previous embodiments. In a Ni film forming process S6 of the current embodiment, a cycle is set so that the cycle includes: a process S6a of forming a Ni film on a substrate according to a CVD method by supplying a Ni-containing source such as Ni(PF₃)₄ into a process vessel and exhausting the Ni-containing source from the process vessel; and a process S6b of purging the inside of the process vessel by supplying an inert gas such as N₂ gas into the process vessel and exhausting the inert gas from the process vessel. The cycle is performed a plurality of times (process S6c) to form a Ni film having a predetermined thickness on the substrate while keeping the P concentration of the Ni film at a low level.

In this case, although a thin Ni film can be formed in the source supply process S6a, impurities such as phosphorus (P) and fluorine (F) generated by decomposition of the source may adhere to the Ni film or permeate the Ni film. However, in the purge process S6b performed after the source supply process S6a, the Ni film is placed under a heated inert atmosphere (N₂ gas atmosphere) so that the impurities such as phosphorus (p) and fluorine (F) can be eliminated by the annealing effect. The eliminated impurities such as P and F are discharged to the outside of the process chamber by purging the process chamber with an inert gas. By minutely repeating the processes a plurality of times, a high-quality Ni film can be thoroughly formed while eliminating impurities adhered to or permeating the Ni film.

As described above, according to the process sequence of the current embodiment, impurities such as P and F generating by decomposition of a source can be prevented from entering a Ni film, and thus the impurity concentration, particularly, the P concentration of the Ni film can be largely reduced. That is, it is possible to form a high-quality Ni film having a low impurity concentration, particularly, a low P concentration. Owing to this, deterioration of device characteristics can be prevented.

### Example 1

### Dependence of Ni Film Resistivity on Pretreatment Time

By using the substrate processing apparatus described in the previous embodiments, a pretreatment process was performed by supplying a reducing gas (H₂ gas or NH₃ gas) to a wafer on which a 100-nm SiO₂ film was formed, and then a Ni film forming process was performed on the wafer by using Ni(PF₃)₄, so as to prepare a wafer having a Ni film formed on a SiO₂ film as an evaluation sample. In addition, a plurality of evaluation samples were prepared while changing the kind of reducing gas and the supply time of the reducing gas in the pretreatment process, and the resistivities of Ni films of the evaluation samples were measured. The pretreatment process and the Ni film forming process were performed according to the same process flows as those of the pretreatment process S5 and the Ni film forming process S6 described in the previous embodiments. In addition, the process temperature (wafer temperature) in the pretreatment process and the Ni film forming process were set to 200° C., and other process conditions were set to values in the process condition ranges of the previous embodiments.

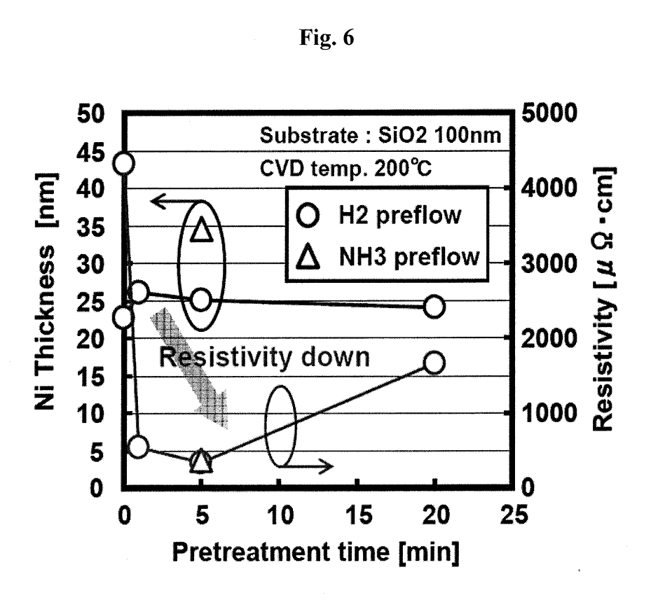

FIG. 6 illustrates the dependence of Ni film resistivities on a pretreatment time in the evaluation samples. The horizontal axis of FIG. 6 denotes a pretreatment time, that is, the supply time (minute) of a reducing gas. In FIG. 6, the left vertical axis denotes thicknesses [nm] of Ni films, and the right vertical axis denotes resistivities [μΩ·cm] of the Ni films. Furthermore, in FIG. 6, white circles denote the case of using H₂ gas as a reducing gas, and white triangles denote the case of using NH₃ gas as a reducing gas. In addition, when the pretreatment time is zero, it means that the pretreatment process was not performed.

Referring to FIG. 6, in the case of using H₂ gas as a reducing gas and the case of using NH₃ gas as a reducing gas in the pretreatment process, although the thicknesses of the Ni films were the same as compared with the case where no pretreatment process was performed, the resistivities of the Ni films were decreased. Although the thicknesses of the pretreated Ni films were the same as the thicknesses of the non-pretreated Ni films, the resistivities of the pretreated Ni films were lower than the resistivities of the non-pretreated Ni films because the pretreatment process made grains of the Ni films closer and increased the grain density of the Ni films to make the Ni films continuous. Particularly, when the pretreatment time ranges from 1 minute to 5 minutes, the resistivity of the Ni film decreases steeply, and when the pretreatment time is 5 minutes, the resistivity of the Ni film becomes minimal. From the experimental data, it can be understood that the implementation of a pretreatment process using a reducing gas makes it possible to increase the grain density of a Ni film and decrease the resistivity of the Ni film.

### Example 2

### Variation of Ni Film Surface Morphology after Pretreatment

By using the substrate processing apparatus described in the previous embodiments, a pretreatment process was performed by supplying a reducing gas (H₂ gas or NH₃ gas) to a wafer on which a 100-nm SiO₂ film was formed, and then a Ni film forming process was performed on the wafer by using Ni(PF₃)₄, so as to prepare a wafer having a Ni film formed on a SiO₂ film as an evaluation sample. In addition, a plurality of evaluation samples were prepared while changing the kind of reducing gas in the pretreatment process, and the surface morphology of Ni films of the evaluation samples were observed by using a scanning electron microscope (SEM observation). The pretreatment process and the Ni film forming process were performed according to the same process flows as those of the pretreatment process S5 and the Ni film forming process S6 described in the previous embodiments. In addition, the process temperature (wafer temperature) in the pretreatment process and the Ni film forming process were set to 200° C., and the reducing gas supply time in the pretreatment process were set to 0 minutes and 5 minutes. However, other process conditions were set to values in the process condition ranges of the previous embodiments. When the reducing gas supply time is 0 minutes, it means that the pretreatment process was not performed.

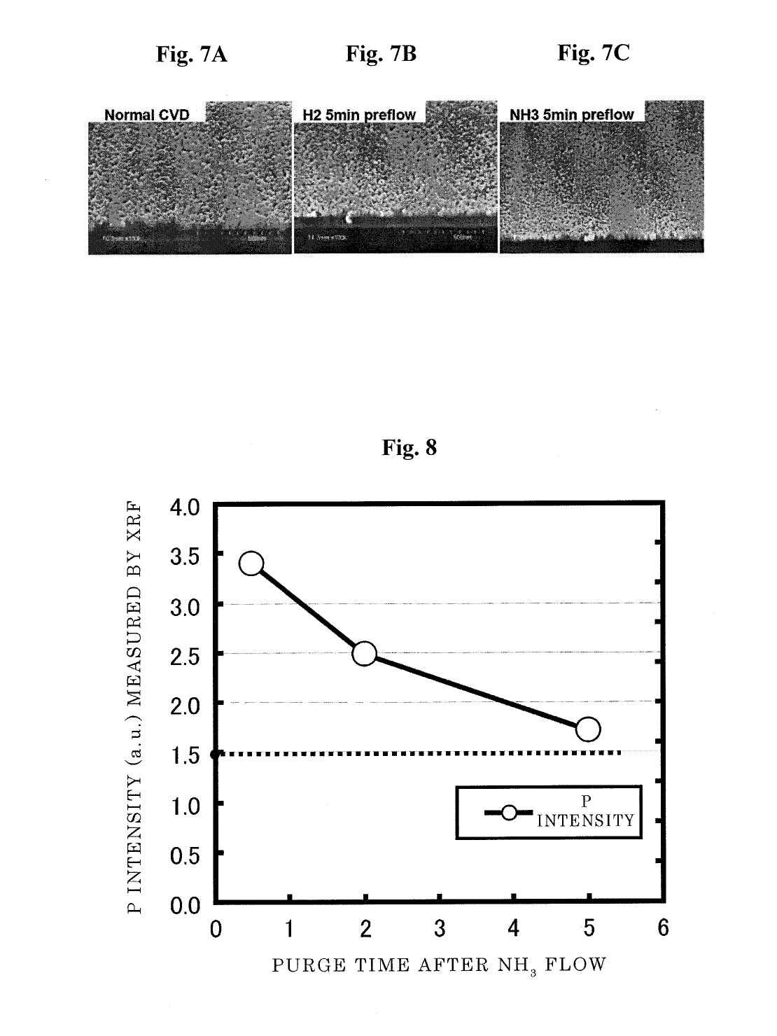

FIG. 7A to FIG. 7C are scanning electron views (SEM images) illustrating the surface morphologies of Ni films for the case where a pretreatment was performed using a reducing gas (H₂ gas, NH₃ gas) and the case where a pretreatment was not performed. ┌Normal CVD┘ of FIG. 7A denotes the case where a pretreatment process was not performed, ┌H₂ 5 min preflow┘ of FIG. 7B denotes the case where a pretreatment process was performed using H₂ gas, and ┌NH₃ 5 min preflow┘ of FIG. 7C denotes the case a pretreatment process was performed using NH₃ gas.

Referring to FIG. 7A to FIG. 7C, both in the case of using H₂ gas as a reducing gas in a pretreatment process and the case of using NH₃ gas as a reducing gas in a pretreatment process, the grain sizes of the Ni films were small, the grain densities of the Ni films were high, and the surface morphologies of Ni films were satisfactory as compared with the case where a pretreatment process was not performed. From the experimental data, it can be understood that the grain size and density of a Ni film can be controlled and a high-quality Ni film having satisfactory surface morphology can be obtained through a pretreatment process using a reducing gas. In addition, it can be understood that the grain size and density of a Ni film can be adjusted to predetermined values by controlling the process conditions of a pretreatment process such as a reducing gas supply time.

### Example 3

### Dependence of P Concentration of Ni Film on Purge Time after Pretreatment Process

By using the substrate processing apparatus described in the previous embodiments, a pretreatment process was performed by supplying NH₃ gas as a reducing gas to a wafer on which a 100-nm SiO₂ film was formed, and then a Ni film forming process was performed on the wafer by using Ni(PF₃)₄, so as to prepare a wafer having a Ni film formed on a SiO₂ film as an evaluation sample. In addition, a plurality of evaluation samples were prepared while changing the time of a N₂ gas purge process performed after the NH₃ gas was supplied but before the Ni(PF₃)₄ was supplied, and the P intensity of Ni films of the evaluation samples were measured by using X-ray fluorescence (XRF) (using an XRF analysis device). The pretreatment process and the Ni film forming process were performed according to the same process flows as those of the pretreatment process S5 and the Ni film forming process S6 described in the previous embodiments. Furthermore, in the pretreatment process and the Ni film forming process, the process temperature (wafer temperature) was set to 200° C., and the time of a purge process performed after the NH₃ gas was supplied but before the Ni(PF₃)₄ was supplied was set to 0.5 minutes (30 seconds), 2 minutes, and 5 minutes. However, other process conditions were set to values in the process conditions ranges of the previous embodiments.

FIG. 8 is a view illustrating the dependence of the P intensities of Ni films on the time of a purge process performed after a pretreatment process. The horizontal axis of FIG. 8 denotes a purge time, that is, the supply time (minute) of N₂ gas supplied after NH₃ gas was supplied but before Ni(PF₃)₄ was supplied. The vertical axis of FIG. 8 denotes the P intensities of the Ni films in arbitrary unit (a.u.). Furthermore, in FIG. 8, the white circles denote the P intensity of the Ni film in the case where a pretreatment process was performed, and the dotted line denotes the P intensity of the Ni film in the case where a pretreatment process was not performed (the case where NH₃ gas was not supplied).

Referring to FIG. 8, when the purge time is 0.5 minutes (30 seconds), the P intensity of the Ni film is relatively high. However, as the purge time increases, the P intensity of the Ni film decreases. When the purge time is 5 minutes, the P intensity of the Ni film is reduced to or below ½ of the P intensity of the Ni film when the purge time is 0.5 minutes (30 seconds), approaching the P intensity of the case where NH₃ gas was not supplied. From the experimental data, it can be understood that: in the case of using a source such as Ni(PF₃)₄ that can easily react with a reducing gas, it is necessary to purge the inside of the process chamber between the supply of a reducing gas and the supply of a source so as to reduce impurities (P concentration) of a Ni film.

### Example 4

### Dependence of P/Ni X-Ray Fluorescence Intensity Ratio on Process Sequence

By using the substrate processing apparatus described in the previous embodiments, a Ni film forming process was performed on a wafer on which a 100-nm SiO₂ film was formed by using Ni(PF₃)₄ as a source so as to prepare a wafer having a Ni film formed on a SiO₂ film as an evaluation sample. In addition, while changing the process sequence, Ni films were formed on evaluation samples. In detail, the following three evaluation samples were prepared, and the P/Ni X-ray fluorescence intensity ratios of the evaluation samples were measured.

(A) An evaluation sample prepared by forming a Ni film through a continuous supply of Ni(PF₃)₄ (conventional CVD).

(B) An evaluation sample prepared by forming a Ni film through alternate supplies of Ni(PF₃)₄ and N₂ (Cyclic N₂ CVD).

(C) An evaluation sample prepared by forming a Ni film through alternate supplies of Ni(PF₃)₄ and H₂ (Cyclic H₂CVD).

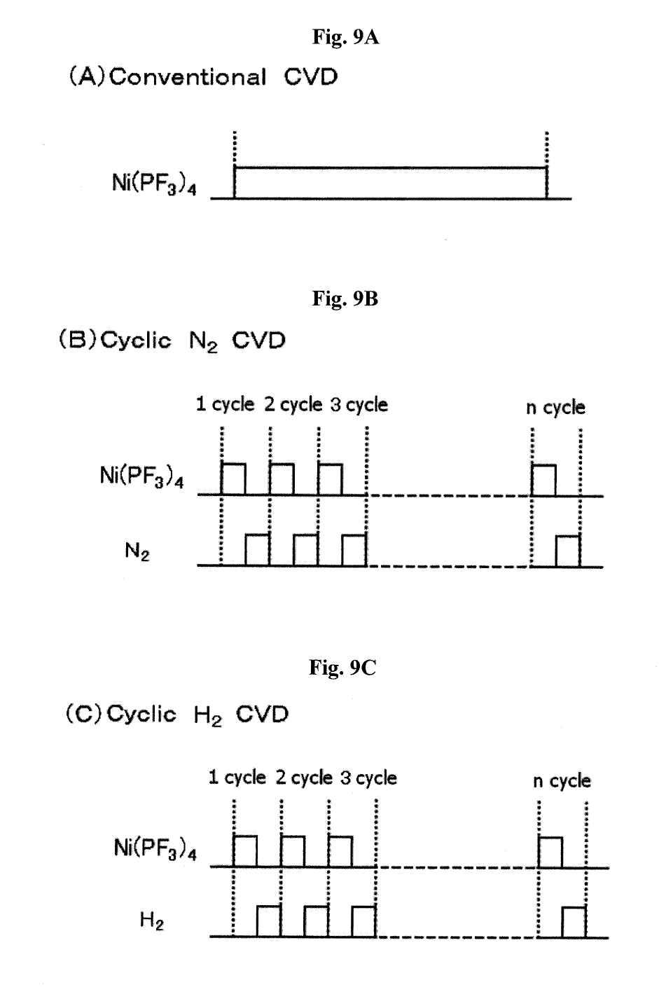

FIG. 9A to FIG. 9C are views illustrating gas supply timing of process sequences used when the evaluation samples were prepared. FIG. 9A illustrates an evaluation sample (A) on which a Ni film was formed by a conventional CVD method. FIG. 9B illustrates an evaluation sample (B) on which a Ni film was formed through a Ni film forming process S6 by performing, a plurality of times, a cycle including a source supply process S6a of supplying Ni(PF₃)₄ and a purge process S6b using N₂ gas. FIG. 9C illustrates an evaluation sample (C) on which a Ni film was formed by performing, a plurality of times, a cycle including a source supply process of supplying Ni(PF₃)₄ and a purge process using H₂ gas. Process conditions used for preparing the evaluation samples were set in the process condition ranges described in the previous embodiments.

FIG. 10 is a view illustrating the P/Ni X-ray fluorescence intensity ratios of the Ni films of the evaluation samples. In FIG. 10, the horizontal axis denotes the evaluation samples, and the vertical axis denotes P/Ni X-ray fluorescent intensity ratios. The P/Ni X-ray fluorescence intensity ratio denotes a P concentration with respect to a Ni concentration. As the P/Ni X-ray fluorescence intensity ratio becomes higher, the P concentration becomes higher, and the P/Ni X-ray fluorescence intensity ratio becomes lower, the P concentration becomes lower.

Referring to FIG. 10, although the P concentration of the Ni film of the evaluation sample (C) (cyclic H₂CVD) is similar to the P concentration of the Ni film of the evaluation sample (A) (conventional CVD), the P concentration of the Ni film of the evaluation sample (B) (cyclic N₂ CVD) is much lower than the P concentration of the Ni film of the evaluation sample (A) (conventional CVD). From the experimental data, it can be understood that a high-quality Ni film having a low impurity concentration, particularly, a low P concentration can be formed by performing, a plurality of times, a cycle including a source supply process of supplying Ni(PF₃)₄ and a purge process using N₂ gas.

### Example 5

### Variation of Ni Film Surface Morphology

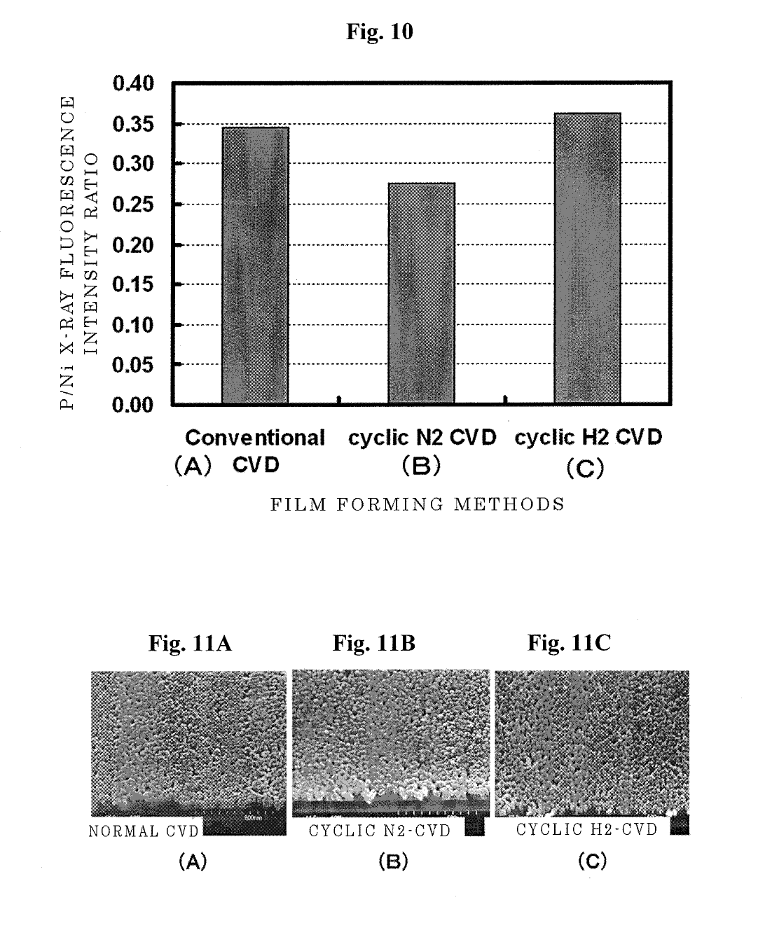

The surface morphologies of the Ni films of the three evaluation samples were observed by a scanning electron microscope (SEM observation). FIG. 11A to FIG. 11C are scanning electron microscope images (SEM images) illustrating the surface morphologies of the Ni films of the evaluation samples. Referring to FIG. 11, as compared with the Ni film of the evaluation sample (A) (conventional CVD), the surface morphology of the evaluation sample (B) (cyclic N₂ CVD) and the surface morphology of the evaluation sample (C) (cyclic H₂ CVD) are not deteriorated. From the experimental data, it can be understood that a high-quality Ni film having a low impurity concentration, particularly, a low P concentration can be formed without deteriorating the surface morphology of the Ni film by a Ni(PF₃)₄ CVD method in which a Ni(PF₃)₄ supply process and a N₂ gas purge process are set to one cycle and the cycle is performed a plurality of times.

As described above, according to the method of manufacturing a semiconductor device and the substrate processing apparatus, deterioration of the surface morphology of a Ni-containing film caused by dependence on an under layer can be prevented, and a continuous film can be formed in a thin-film region. In addition, According to the method of manufacturing a semiconductor device and the substrate processing apparatus, deterioration of device characteristics caused by impurities included in a film can be prevented, and a high-quality film having a low impurity concentration can be formed.

(Supplementary Note)

The present invention also includes the following preferred embodiments.

According to an embodiment of the present invention, there is provided a method of manufacturing a semiconductor device, the method including:

loading a substrate into a process vessel;

heating the substrate in the process vessel;

pretreating the heated substrate by supplying a reducing gas into the process vessel and exhausting the reducing gas from the process vessel;

removing the reducing gas remaining in the process vessel by supplying an inert gas into the process vessel and exhausting the inert gas from the process vessel;

after the reducing gas is removed from the process vessel, forming a nickel-containing film on the heated and pretreated substrate to a predetermined thickness by supplying a nickel-containing source into the process vessel and exhausting the nickel-containing source from the process vessel; and

unloading the substrate from the process vessel.

Preferably, the forming of the nickel-containing film may include a cycle of: forming a nickel-containing film on the substrate by a CVD method by supplying the nickel-containing source into the process vessel and exhausting the nickel-containing source; and purging an inside of the process vessel by supplying the inert gas into the process vessel and exhausting the inert gas from the process vessel, wherein the cycle may be performed a plurality of times.

Preferably, the nickel-containing source may be a source containing nickel and phosphorus.

Preferably, the nickel-containing source may be a source containing nickel, phosphorus, and fluorine.

Preferably, the nickel-containing source may be Ni(PF₃)₄.

Preferably, the reducing gas may be H₂ gas or NH₃ gas.

Preferably, the pretreating of the heated substrate and the forming of the nickel-containing film may be performed while keeping the substrate in the same temperature range.

Preferably, the nickel-containing film may be formed by a CVD method.

According to another embodiment of the present invention, there is provided a method of manufacturing a semiconductor device, the method including:

loading a substrate into a process vessel;

forming a nickel-containing film on the substrate to a predetermined thickness; and

unloading the substrate from the process vessel,

wherein the forming of the nickel-containing film is carried out by performing, a plurality of times, a cycle including:

forming a nickel-containing film on the substrate by a CVD method by supplying a nickel-containing source into the process vessel and exhausting the nickel-containing source from the process vessel; and

purging an inside of the process vessel by supplying an inert gas into the process vessel and exhausting the inert gas from the process vessel.

Preferably, the nickel-containing source may be a source containing nickel and phosphorus.

Preferably, the nickel-containing source may be a source containing nickel, phosphorus, and fluorine.

Preferably, the nickel-containing source may be Ni(PF₃)₄.

According to another embodiment of the present invention, there is provided a substrate processing apparatus including:

a process vessel in which a substrate is processed;

a reducing gas supply system configured to supply a reducing gas into the process vessel;

an inert supply system configured to supply an inert gas into the process vessel:

a source supply system configured to supply a nickel-containing source into the process vessel;

an exhaust system configured to exhaust an inside of the process vessel;

a heater configured to heat the substrate in the process vessel; and

a control unit configured to control the reducing gas supply system, the inert gas supply system, the source supply system, the exhaust system, and the heater, so as to: heat the substrate in the process vessel; pretreat the heated substrate by supplying the reducing gas into the process vessel and exhausting the reducing gas from the process vessel; remove the reducing gas remaining in the process vessel by supplying the inert gas into the process vessel and exhausting the inert gas from the process vessel; and form a nickel-containing film on the heated and pretreated substrate to a predetermined thickness by supplying the nickel-containing source into the process vessel and exhausting the nickel-containing source from the process vessel after the reducing gas is removed.

According to another embodiment of the present invention, there is provided a substrate processing apparatus including:

a process vessel in which a substrate is processed;

a source supply system configured to supply a nickel-containing source into the process vessel;

an inert gas supply system configured to supply an inert gas into the process chamber;

an exhaust system configured to exhaust an inside of the process vessel; and

a control unit configured to control the source supply system, the inert gas supply system, and the exhaust system so as to form a nickel-containing film on the substrate to a predetermined thickness by performing, a plurality of times, a cycle including: forming a nickel-containing film on the substrate by a CVD method by supplying the nickel-containing source into the process vessel and exhausting the nickel-containing source from the process vessel; and purging an inside of the process vessel by supplying the inert gas into the process vessel and exhausting the inert gas from the process vessel.

What is claimed is:

1. A method of manufacturing a semiconductor device, the method comprising:
loading a substrate into a process vessel;
heating the substrate in the process vessel;
pretreating the heated substrate by supplying a reducing gas into the process vessel and exhausting the reducing gas from the process vessel;
removing the reducing gas remaining in the process vessel by supplying an inert gas into the process vessel and exhausting the inert gas from the process vessel;
after the reducing gas is removed from the process vessel, forming a nickel-containing film on the heated and pretreated substrate to a predetermined thickness by supplying a nickel-containing source into the process vessel and exhausting the nickel-containing source from the process vessel; and
unloading the substrate from the process vessel.

2. The method of claim 1, wherein the forming of the nickel-containing film comprises a cycle of:
forming a nickel-containing film on the substrate by a chemical vapor deposition (CVD) method by supplying the nickel-containing source into the process vessel and exhausting the nickel-containing source; and
purging an inside of the process vessel by supplying the inert gas into the process vessel and exhausting the inert gas from the process vessel,
wherein the cycle is performed a plurality of times.

3. The method of claim 1, wherein the nickel-containing source is a source containing nickel and phosphorus.

4. The method of claim 1, wherein the nickel-containing source is a source containing nickel, phosphorus, and fluorine.

5. The method of claim 1, wherein the nickel-containing source is Ni(PF₃)₄.

6. The method of claim 1, wherein the reducing gas is H₂ gas or NH₃ gas.

7. The method of claim 5, wherein the reducing gas is H₂ gas or NH₃ gas.

8. The method of claim 1, wherein the pretreating of the heated substrate and the forming of the nickel-containing film are performed while keeping the substrate in the same temperature range.

9. The method of claim 1, wherein the nickel-containing film is formed by a CVD method.

10. A method of manufacturing a semiconductor device, the method comprising:
loading a substrate into a process vessel;
forming a nickel-containing film on the substrate to a predetermined thickness; and
unloading the substrate from the process vessel,
wherein the forming of the nickel-containing film is carried out by performing, a plurality of times, a cycle comprising:
forming a nickel-containing film on the substrate by a CVD method by supplying a nickel-containing source into the process vessel and exhausting the nickel-containing source from the process vessel; and
purging an inside of the process vessel by supplying an inert gas into the process vessel and exhausting the inert gas from the process vessel.

11. The method of claim 10, wherein the nickel-containing source is a source containing nickel and phosphorus.

12. The method of claim 10, wherein the nickel-containing source is a source containing nickel, phosphorus, and fluorine.

13. The method of claim 10, wherein the nickel-containing source is Ni(PF₃)₄.

14. A substrate processing apparatus comprising:
a process vessel in which a substrate is processed;
a reducing gas supply system configured to supply a reducing gas into the process vessel;
an inert gas supply system configured to supply an inert gas into the process vessel:
a source supply system configured to supply a nickel-containing source into the process vessel;
an exhaust system configured to exhaust an inside of the process vessel;
a heater configured to heat the substrate in the process vessel; and
a control unit configured to control the reducing gas supply system, the inert gas supply system, the source supply system, the exhaust system, and the heater so as to: heat the substrate in the process vessel; pretreat the heated substrate by supplying the reducing gas into the process vessel and exhausting the reducing gas from the process vessel; remove the reducing gas remaining in the process vessel by supplying the inert gas into the process vessel and exhausting the inert gas from the process vessel; and form a nickel-containing film on the heated and pretreated substrate to a predetermined thickness by supplying the nickel-containing source into the process vessel and exhausting the nickel-containing source from the process vessel after the reducing gas is removed.
